(19) United States
(12) Patent Application Publication
(10) Pub. No.: US 2012/0147562 A1
(43) Pub. Date: Jun. 14, 2012

(54) HEAT EXCHANGER, HEAT DISSIPATION METHOD OF THE SAME AND COMMUNICATION APPARATUS

(76) Inventors: Taqing FENG, Shenzhen (CN); Yuping Hong, Shenzhen (CN); Hui Lin, Shenzhen (CN); Feng Peng, Shanghai (CN); Yunhul Zhang, Shenzhen (CN); Chong Wu, Shenzhen (CN)

(21) Appl. No.: 13/327,236

(22) Filed: Dec. 15, 2011

(30) Foreign Application Priority Data
Jun. 15, 2009 (CN) 200910107884.X
May 28, 2010 (CN) PCT/CN2010/073327

(51) Int. Cl. H05K 7/20; F28F 13/06; F28F 3/12; F28D 15/04

(52) U.S. Cl. 361/696; 165/104.26; 165/121; 165/166

(57) ABSTRACT

A heat exchanger, a heat dissipation method and a communication apparatus are provided. The heat exchanger includes a first and a second air passage separated from each other. The first air passage has a first fan unit and a first group of heat dissipation tubules. The second air passage has a second fan unit and a second group of heat dissipation tubules. The upper ends of the first and second group of heat dissipation tubules are communicated with each other via a steam manifold. The lower ends of the first and second group of heat dissipation tubules are communicated with each other via a liquid manifold. A closed pipeline filled with liquid vaporized when heated, is formed by the first and second group of dissipation tubules, the steam manifold and the liquid manifold. Heat dissipation fins are set among the first and second group of dissipation tubules.

### CROSS-REFERENCE TO RELATED APPLICATIONS

This application claims priority to Chinese Patent Application No. 200910107884.X, entitled “heat exchanger, heat dissipation method of the same and communication apparatus”, and filed on Jun. 15, 2009, which is hereby incorporated by reference in its entirety.

### FIELD OF THE INVENTION

The present invention relates to the field of heat dissipation technique, and particularly, to a heat exchanger, a heat dissipation method of the same and a communication apparatus.

### BACKGROUND OF THE INVENTION

With the development of the communication technique, the integration level of the communication apparatus is increasingly higher, and the heat consumption in the unit space is continuously increased. Meanwhile, in order to meet the market demand in the communication field, the application arrange of the communication apparatus becomes more and more extensive. For an outdoor communication apparatus, the most prominent feature is that the communication apparatus is suitable to various territorial environments and temperatures. Thus the outdoor communication apparatus should solve the problem of heat dissipation in different territorial environments and different temperatures.

Referring to FIGS. 1-2, which illustrate a way for the outdoor communication apparatus in the prior art to dissipate heat with a heat exchanger. As illustrated in FIG. 1, a heat exchanger 10 includes a plate-type heat exchanger core 11 that forms two independent air passages, i.e., a first air passage 15 and a second air passage 13. The air inlet of the second air passage 13 is provided with a second circulation centrifugal fan 17 for directing the air outside the communication apparatus into the second air passage 13, and the air inlet of the first air passage 15 is provided with a first circulation centrifugal fan 19 for directing the air inside the communication apparatus into the first air passage 15. As illustrated in FIG. 2, the plate-type heat exchanger core 11 is composed of a partition board that forms the first air passage 15 and the second air passage 13 by being bent.

During the heat dissipation of the communication apparatus, under the action of the first circulation centrifugal fan 19, the air inside the communication apparatus passes the first air passage 15 of the plate-type heat exchanger core 11, and under the action of the second circulation centrifugal fan 17, the air outside the communication apparatus passes the second air passage 13 of the plate-type heat exchanger core 11. Thus, when the air in the first air passage 15 passes the plate-type heat exchanger core 11, the air outside the communication apparatus passes the second air passage 13, and heat exchange is performed between the air in the first and second air passages 15, 13, thereby reducing the air temperature in the communication apparatus, and realizing the heat exchange between the air inside and outside the communication apparatus.

During the implementation of the present invention, the inventors find that the prior art at least has the following defect.

In the prior art, the plate-type heat exchanger core 11 is composed of a partition board, thus the flow resistance is large when the air outside the communication apparatus passes the second air passage 13 of the plate-type heat exchanger core 11, and the air inside the communication apparatus passes the first air passage 15 of the plate-type heat exchanger core 11. As a result, with the increased power of the communication apparatus, it is difficult for the plate-type heat exchanger core to meet the heat dissipation requirement of the communication apparatus.

### SUMMARY OF THE INVENTION

The embodiments of the present invention provide a heat exchanger, a heat dissipation method of the same and a communication apparatus, which meet the heat dissipation requirement of the communication apparatus.

The embodiments of the present invention provide a heat exchanger including a first air passage and a second air passage separated from each other, wherein the first air passage is provided with a first fan unit and a first group of heat dissipation tubules; the second air passage is provided with a second fan unit and a second group of heat dissipation tubules; the upper ends of the first group of heat dissipation tubules along the gravity direction are communicated via a steam manifold with the upper ends of the second group of heat dissipation tubules along the gravity direction, the lower ends of the first group of heat dissipation tubules along the gravity direction are communicated via a liquid manifold with the lower ends of the second group of heat dissipation tubules along the gravity direction; a closed pipeline, which is filled with liquid vaporized when being heated, is formed by the first group of dissipation tubules, the steam manifold, the second group of dissipation tubules and the liquid manifold; heat dissipation fins are set among the first group of dissipation tubules and the second group of dissipation tubules.

The embodiments of the present invention further provide a heat dissipation method of heat exchanger. The method includes, the air inside a communication apparatus passing a first air passage under the action of a first fan unit, and the air outside the communication apparatus passing a second air passage under the action of a second fan unit, wherein the first and second air passages are separated from each other; carrying out a heat exchange between the air inside the communication apparatus passing the first air passage and the liquid in a first group of heat dissipation tubules, so that the liquid in the first group of heat dissipation tubules is vaporized into a steam by absorbing heat, and the steam flows along a steam manifold into a second group of heat dissipation tubules; and carrying out a heat exchange between the air outside the communication apparatus passing the second air passage and the steam passing the second group of heat dissipation tubules, so that the steam passing the second group of heat dissipation tubules is condensed into liquid, which flows into the first group of heat dissipation tubules via a liquid manifold.

The embodiments of the present invention further provide a communication apparatus, which includes a cabinet and a heat exchanger, the cabinet is provided with a single board and the heat exchanger is disposed in the cabinet, the heat exchanger includes a first air passage and a second air passage separated from each other, the first air passage is communicated with the air inside the cabinet, and the second air passage is communicated with the air outside the cabinet, wherein the first air passage is provided with a first fan unit and a first group of heat dissipation tubules; the second air passage is provided with a second fan unit and a second group of heat dissipation tubules; the upper ends of the first group of heat dissipation tubules along the gravity direction are communicated via a steam manifold with the upper ends of the second group of heat dissipation tubules along the gravity direction, the lower ends of the first group of heat dissipation tubules along the gravity direction are communicated via a liquid manifold with the lower ends of the second group of heat dissipation tubules along the gravity direction; a closed pipeline, which is filled with liquid vaporized when being heated, is formed by the first group of dissipation tubules, the steam manifold, the second group of dissipation tubules and the liquid manifold; heat dissipation fins are set among the first group of dissipation tubules and the second group of dissipation tubules.

From the above content, it can be seen that the first group of dissipation tubules are filled with the liquid vaporized when being heated and the liquid vaporized when being heated flows in the first group of dissipation tubules and the second group of dissipation tubules, thus there is a small flow resistance for the air inside and outside the communication apparatus to pass the heat dissipation tubules. So with the increase of the power of the communication apparatus, the heat dissipation requirement of the communication apparatus can be well satisfied.

### BRIEF DESCRIPTION OF THE DRAWINGS

In order to more clearly describe the technical solutions of the embodiments of the present invention or the prior art, the drawings to be used in the descriptions of the embodiments or the prior art are briefly introduced as follows. Obviously, the following drawings just illustrate some embodiments of the present invention, and a person skilled in the art can obtain other drawings from these drawings without paying a creative effort.

FIG. 1 is a schematic diagram of a heat exchanger in the prior art;

FIG. 2 is a structure diagram of a plate-type heat exchanger core of a heat exchanger in the prior art;

FIG. 3 is a three-dimensional structure diagram of a heat exchanger according to an embodiment of the present invention;

FIG. 4 is a schematic diagram of a second circulation side of a heat exchanger according to an embodiment of the present invention;

FIG. 5 is a schematic diagram of a first circulation side of a heat exchanger according to an embodiment of the present invention;

FIG. 6 is a schematic diagram in which heat dissipation fins are set among a first group of dissipation tubules of a heat exchanger according to an embodiment of the present invention;

FIG. 7 is a partial enlarged diagram of Part A as illustrated in FIG. 6 according to an embodiment of the present invention;

FIG. 8 is a schematic diagram of configurations in front-back direction of first and second air passages of a heat exchanger according to an embodiment of the present invention;

FIG. 9 is a schematic diagram of configurations in up-down direction of first and second air passages of a heat exchanger according to an embodiment of the present invention;

FIG. 10 is a schematic diagram of a heat dissipation manner of the heat exchanger as illustrated in FIG. 9; and

FIG. 11 is a schematic diagram of a heat dissipation method of a heat exchanger according to an embodiment of the present invention.

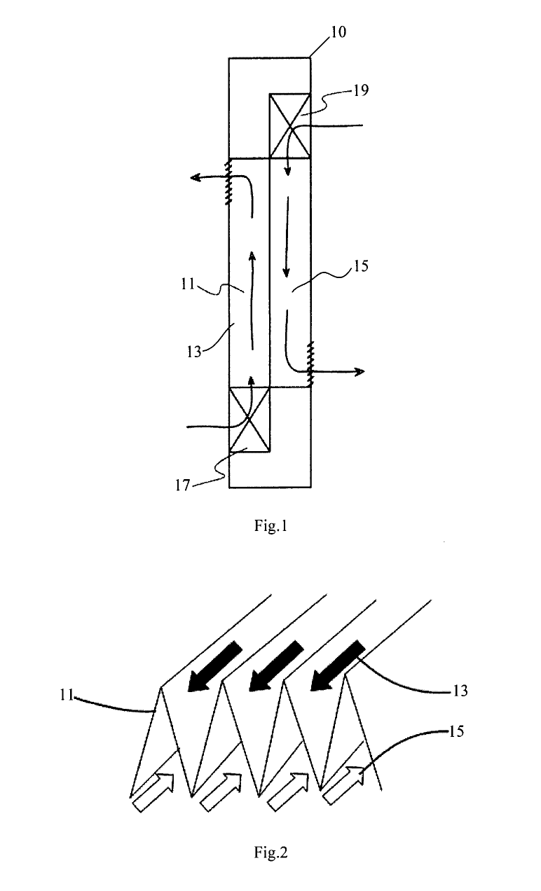

### DETAILED DESCRIPTION OF THE EMBODIMENTS

The technical solutions of the embodiments of the present invention will be clearly and completely described as follows in conjunction with the drawings. Obviously, the described embodiments are just a part of the embodiments of the present invention rather than all the embodiments. Based on the embodiments of the present invention, any other embodiment obtained by a person skilled in the art without paying any creative effort shall fall within the protection scope of the present invention.

### Embodiment 1

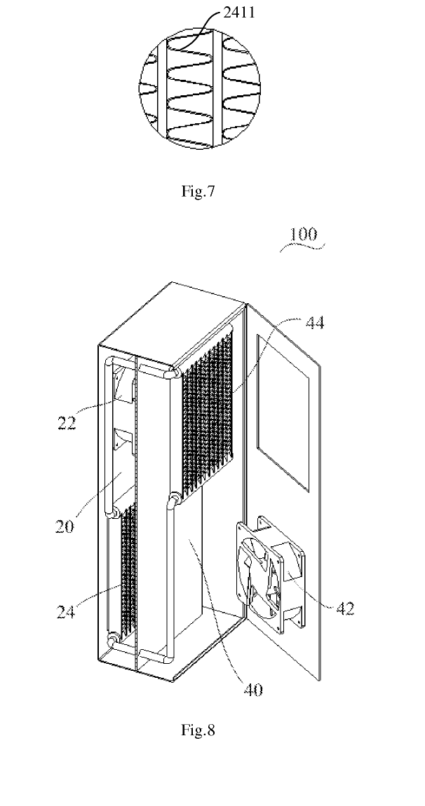

Referring to FIGS. 3, 6 and 7, wherein FIG. 3 is a three-dimensional structure diagram of a heat exchanger according to an embodiment of the present invention, FIG. 6 is a schematic diagram of a first group of dissipation tubules, and FIG. 7 is a partial enlarged diagram of Part A as illustrated in FIG. 6. The heat exchanger 100 includes a first air passage 20 and a second air passage 40. The first air passage 20 and the second air passage 40 are separated from each other, and the first air passage 20 is provided with a first fan unit 22 and a first group of heat dissipation tubules 24, and the second air passage 40 is provided with a second fan unit 42 and a second group of heat dissipation tubules 44. The upper ends 247 of the first group of heat dissipation tubules 24 along the gravity direction are communicated via a steam manifold 80 with the upper ends 447 of the second group of heat dissipation tubules 44 along the gravity direction. The lower ends 249 of the first group of heat dissipation tubules 24 along the gravity direction are communicated via a liquid manifold 60 with the lower ends 449 of the second group of heat dissipation tubules 44 along the gravity direction. A closed pipeline, which is filled with liquid vaporized when being heated, is formed by the first group of dissipation tubules 24, the steam manifold 80, the second group of dissipation tubules 44 and the liquid manifold 60. Heat dissipation fins 2411 are set among the first group of dissipation tubules 24 and the second group of dissipation tubules 44.

From the above content, it can be seen that the first group of heat dissipation tubules 24 and the second group of heat dissipation tubules 44 of the heat exchanger 100 according to the embodiment of the present invention are arranged separately. The first group of heat dissipation tubules 24 adopts a first group of heat dissipation tubules 241, and the second group of heat dissipation tubules 44 adopts a second group of heat dissipation tubules 441. The first group of heat dissipation tubules 241 is filled with liquid that is vaporized when being heated and flows in a one-way circulation of liquid→steam→liquid. Meanwhile, the flow resistance is small for the airflow (the air inside and outside the communication apparatus) to pass the heat dissipation tubules. Therefore, with the increase of the power of the communication apparatus, the heat dissipation requirement of the communication apparatus can be well satisfied.

Meanwhile, the small flow resistance is also small for the airflow (the air inside and outside the communication apparatus) to pass the heat dissipation fins, and the heat exchange area between the airflow and the outer surfaces of the heat dissipation tubules (the first group of heat dissipation tubules 24 and the second group of heat dissipation tubules 44) can be increased by the heat dissipation fins.

The upper ends 447 of the second group of heat dissipation tubules 44 along the gravity direction are not lower than the upper ends 247 of the first group of heat dissipation tubules 24, and the lower ends 449 of the second group of heat dissipation tubules 44 are not lower than the lower ends 249 of the first group of heat dissipation tubules 24.

The steam manifold 80 includes a first upper manifold 243 and a second upper manifold 443 which communicate with each other via a pipeline 82. The liquid manifold 60 includes a second lower manifold 445 and a first lower manifold 245 which communicate with each other via a pipeline 62.

Further, referring to FIGS. 3 and 6, the upper ends 247 of the first group of heat dissipation tubules 24 along the gravity direction are communicated with the first upper manifold 243, and the lower ends 249 of the first group of heat dissipation tubules 24 along the gravity direction are communicated with the first lower manifold 245. Similarly, the lower ends 449 of the second group of heat dissipation tubules 44 along the gravity direction are communicated with the second lower manifold 445, and the upper ends 447 of the second group of heat dissipation tubules 44 along the gravity direction are communicated with the second upper manifold 443.

Referring to FIG. 6, the first group of heat dissipation tubules 24 may be parallel with each other, and similarly, the second group of heat dissipation tubules 44 may also be parallel with each other. The first and second groups of heat dissipation tubules 24, 44 are a plurality of tabular heat dissipation tubules and arranged upright along the gravity direction, as illustrated in FIG. 3.

Further, referring to FIGS. 6 and 7, FIG. 6 is a schematic diagram of the first group of dissipation tubules 24, and FIG. 7 is a partial enlarged diagram of Part A as illustrated in FIG. 6. The heat dissipation fins 2411 are set among the first group of dissipation tubules 24 by means of vacuum brazing.

It shall be appreciated that the heat dissipation fins 2411 may also be set among the second group of heat dissipation tubules 44 by means of vacuum brazing. The heat dissipation fins 2411 set among the first group of heat dissipation tubules 24 and the second group of heat dissipation tubules 44 can greatly increase the heat exchange area between the airflow and the outer surfaces of the heat dissipation tubules (the first group of heat dissipation tubules 24 and the second group of heat dissipation tubules 44).

To be noted, as illustrated in FIG. 7, the heat dissipation fins 2411 have a corrugated shape. Of course, the heat dissipation fins 2411 may have a zigzag shape. The heat dissipation fins 2411 among the first group of heat dissipation tubules 241 may be corrugated heat dissipation fins, and those among the second group of heat dissipation tubules 441 may be zigzag heat dissipation fins. The embodiments of the present invention are not limited thereto.

The heat dissipation manner of the heat exchanger 100 is described as follows.

Referring to FIGS. 3, 4 and 6, in case the communication apparatus is provided with the heat exchanger 100 for a heat dissipation, the hot air inside the communication apparatus (as shown by the block arrow in FIG. 3) passes the first air passage 20 (i.e., the internal circulation air passage) under the action of the first fan unit 22, and passes the first group of heat dissipation tubules 24. Meanwhile, under the action of the second fan unit 42, the air outside the communication apparatus (as shown by the white arrow in FIG. 3) passes the second air passage 40 (i.e., the external circulation air passage). Thus, a heat exchange is carried out between the liquid filling the first group of heat dissipation tubules 241 and the air inside the communication apparatus passing the first air passage 20, such that the liquid in the first group of heat dissipation tubules 241 is vaporized into a steam by absorbing heat. The steam flows into the steam manifold 80 along the upper ends 247 of the first group of heat dissipation tubules 24 along the gravity direction (i.e., the steam flows into the first upper manifold 243 along the upper ends 247 of the first group of heat dissipation tubules 24 along the gravity direction, and then flows into the second upper manifold 443 via the pipeline 82), and then enters the second group of heat dissipation tubules 44. A heat exchange is carried out between the air outside the communication apparatus passing the second air passage 40 and the steam flowing into the second group of heat dissipation tubules 44, such that the steam in the second group of heat dissipation tubules 44 is condensed into liquid. The liquid flows into the first group of heat dissipation tubules 24 via the liquid manifold 60 (i.e., the liquid flows along the second group of heat dissipation tubules 44 into the lower ends 449 of the second group of heat dissipation tubules 44 along the gravity direction, then flows into the first lower manifold 245 via the pipeline 62, and finally enters the first group of heat dissipation tubules 24).

According to the above process, in the first group of heat dissipation tubules 24 and the second group of heat dissipation tubules 44, the liquid flows in a one-way circulation of liquid→steam→liquid in the closed pipeline formed by the first group of dissipation tubules 24, the steam manifold 80, the second group of dissipation tubules 44 and the liquid manifold 60, so as to perform a heat dissipation for the communication apparatus.

From the above content, it can be seen that under the action of the first fan unit 22, the hot air inside the communication apparatus passes the first air passage 20, and under the action of the second fan unit 42, the air outside the communication apparatus passes the second air passage 40. Meanwhile, in the first group of heat dissipation tubules 24 and the second group of heat dissipation tubules 44, the liquid flows in a one-way circulation of liquid→steam→liquid. The flow resistance for the airflow (the air inside and outside the communication apparatus) to pass the heat dissipation tubules and the heat dissipation fins is small, thus the heat dissipation requirement of the communication apparatus can be satisfied.

Still referring to FIG. 3, along the gravity direction of the heat exchanger 100, the second upper manifold 443 is higher than the first upper manifold 243, and the second lower manifold 445 is higher than the first lower manifold 245. Thus, the liquid is in a better circular flow along the first lower manifold 245, the first group of heat dissipation tubules 24, the first upper manifold 243, the second upper manifold 443, the second group of heat dissipation tubules 44 and the second lower manifold 445.

It shall be appreciated that the second upper manifold 443 and the first upper manifold 243 may at the same height (i.e., flush), and the second lower manifold 445 and the first lower manifold 245 may at the same height (i.e., flush).

The first group of heat dissipation tubules 241 and/or the second group of heat dissipation tubules 441 may be tabular tubules.

The liquid vaporized when being heated may be ammonia, acetone or R134A refrigerant, etc.

The first fan unit 22 and the second fan unit 42 in the above embodiment may be axial flow fans or centrifugal fans. The embodiments of the present invention are not limited thereto.

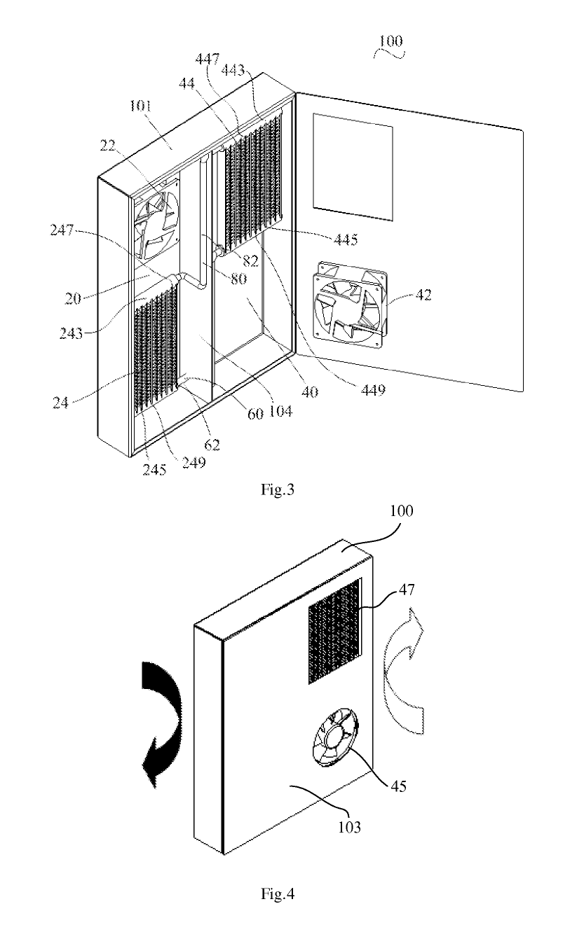

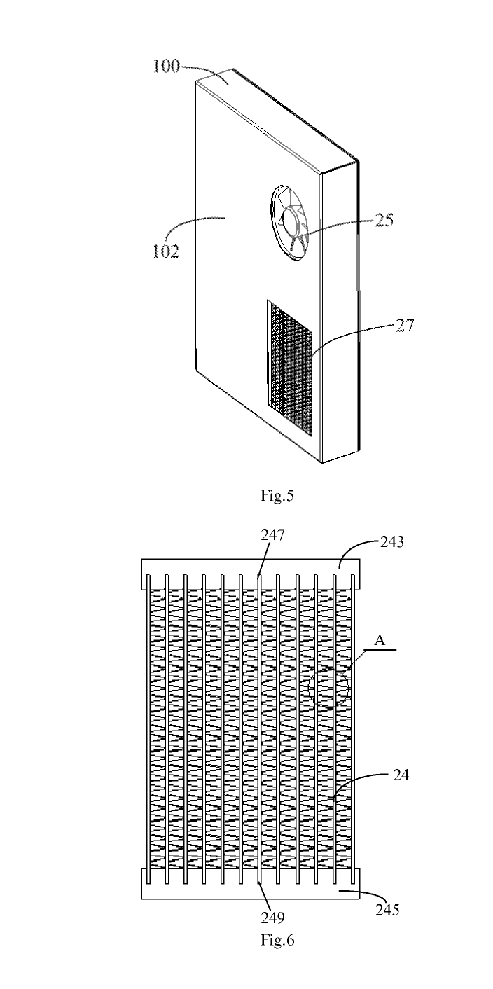

Still referring to FIGS. 3 and 4, wherein FIG. 4 is a schematic diagram of a second circulation side (i.e., the external circulation air passage side) of the heat exchanger according to an embodiment of the present invention. The second air passage 40 includes a second air inlet 45 and a second air outlet 47, wherein the second fan unit 42 is provided at the second air inlet 45, and the second group of heat dissipation tubules 44 is provided at the second air outlet 47.

Specifically, referring to FIGS. 3-5, the heat exchanger 100 includes a housing 101, and a first air inlet 25 and a first air outlet 27 are provided on a first side 102 of the housing 101, and a second air inlet 45 and a second air outlet 47 are provided on a second side 103 of the housing 101. The first side 102 and the second side 103 are opposite to each other, and the first air inlet 25 and the first air outlet 27 are separated from the second air inlet 45 and the second air outlet 47 through a partition board 104. The second fan unit 42 is provided at the second air inlet 45, and the second group of heat dissipation tubules 44 are provided at the second air outlet 47. The first fan unit 22 is provided at the first air inlet 25, and the first group of heat dissipation tubules 24 are provided at the first air outlet 27.

The first group of heat dissipation tubules 24 and the second group of heat dissipation tubules 44 and the connection relation between them may refer to the description of FIG. 3, and herein are not repeated.

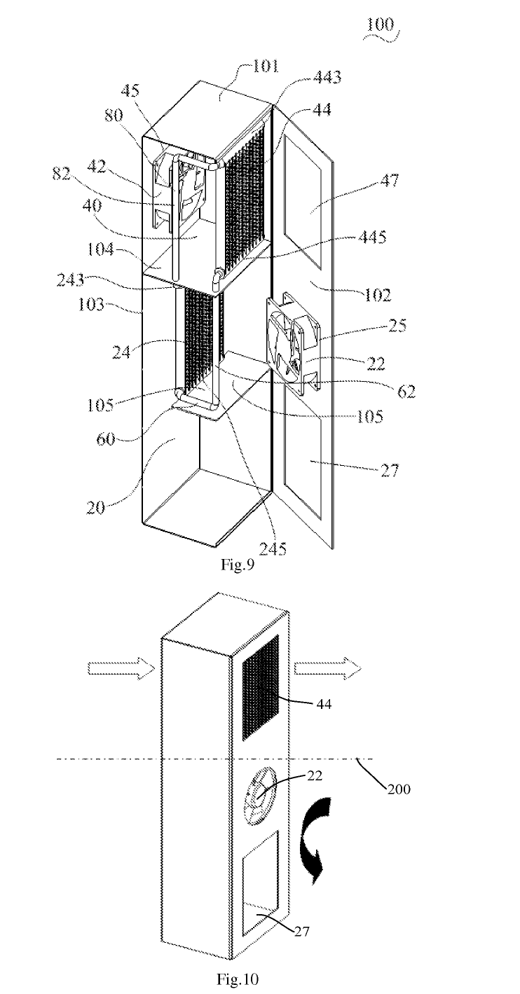

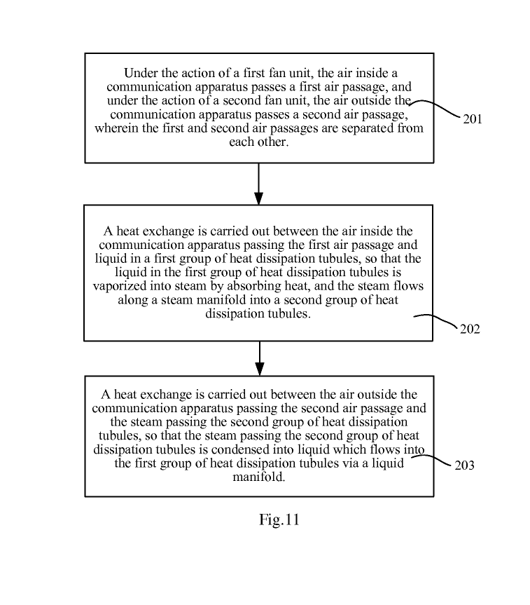

To be noted, referring to FIG. 3, the first air passage 20 and the second air passage 40 are arranged in the left-right direction. Referring to FIG. 8, it shall be appreciated that the first air passage 20 and the second air passage 40 may also be arranged in the front-back direction. Referring to FIG. 10, the first air passage 20 and the second air passage 40 may also be arranged in the up-down direction. The embodiments of the present invention are not limited thereto.

Please see the descriptions of FIG. 3-8 for the front-back arrangement of the first air passage 20 and the second air passage 40, and herein is not repeated.

Specifically, referring to FIG. 9, the positional relations between the first air passage 20 and the second air passage40, as well as the first group of heat dissipation tubules 24 and the second group of heat dissipation tubules 44 are different from those in FIGS. 3-5.

Still referring to FIG. 9, the heat exchanger 100 includes a housing 101. A first air inlet 25, a first air outlet 27 and a second air outlet 47 are provided on a first side 102 of the housing 101, and a second air inlet 45 is provided on a second side 103 of the housing 101. The first side 102 and the second side 103 are opposite to each other, and the first air inlet 25 and the first air outlet 27 are separated from the second air inlet 45 and the second air outlet 47 by a partition board 104. The second fan unit 42 is provided at the second air inlet 45, and the second group of heat dissipation tubules 44 are provided at the second air outlet 47. The first fan unit 22 is provided at the first air inlet 25, and the first group of heat dissipation tubules 24 are provided at the inner surface of the second side 103 and opposite to the first fan unit 22. The first air inlet 25 and the first air outlet 27 are separated from each other by a partition board 105, so that the air inside the communication apparatus flows thereto via the first air inlet 25, passes the first group of heat dissipation tubules 241, and enters into the communication apparatus from the first air outlet 27.

The first group of heat dissipation tubules 24, the second group of heat dissipation tubules 44 and the connection relation between them may refer to the description of FIG. 3, and herein are not repeated.

Referring to FIGS. 3, 9 and 10, wherein FIG. 10 is a schematic diagram of a way for heat dissipation of the heat exchanger as illustrated in FIG. 9. The heat exchanger 100 is provided in the communication apparatus, and specifically, the part below the dotted line 200 is enclosed in the communication apparatus, and the part above the dotted line 200 is exposed to the air outside the communication apparatus. When the heat exchanger 100 performs heat dissipation for the communication apparatus, under the action of the first fan unit 22, the hot air inside the communication apparatus (as shown by the block arrow in FIG. 10) passes the first air passage 20 (i.e., the internal circulation air passage) and the first group of heat dissipation tubules 24. Meanwhile, under the action of the second fan unit 42, the air outside the communication apparatus (as shown by the white arrow in FIG. 10) passes the second air passage 40 (i.e., the external circulation air passage). Thus, a heat exchange is carried out between the liquid filling the first group of heat dissipation tubules 241 and the air inside the communication apparatus passing the first air passage 20, so that the liquid in the first group of heat dissipation tubules 241 is vaporized into steam by absorbing heat. The steam flows into the steam manifold 80 along the upper ends 247 of the first group of heat dissipation tubules 24 along the gravity direction (i.e., the steam flows into the first upper manifold 243 along the upper ends 247 of the first group of heat dissipation tubules 24 along the gravity direction, and then flows into the second upper manifold 443 via the pipeline 82), and then enters into the second group of heat dissipation tubules 44. A heat exchange is carried out between the air outside the communication apparatus passing the second air passage 40 and a steam flowing into the second group of heat dissipation tubules 44, so that the steam in the second group of heat dissipation tubules 44 is condensed into liquid which flows into the first group of heat dissipation tubules 24 via the liquid manifold 60 (i.e., the liquid flows along the second group of heat dissipation tubules 44 into the lower ends 449 of the second group of heat dissipation tubules 44 along the gravity direction, then flows into the first lower manifold 245 via the pipeline 62, and finally enters the first group of heat dissipation tubules 24). According to the above process, in the first group of heat dissipation tubules 24 and the second group of heat dissipation tubules 44, the liquid flows in a one-way circulation of liquid→steam→liquid, so as to perform a heat dissipation for the communication apparatus.

From the above content, it can be seen that under the action of the first fan unit 22, the hot air inside the communication apparatus passes the first air passage 20, and under the action of the second fan unit 42, the air outside the communication apparatus passes the second air passage 40. Meanwhile, in the first group of heat dissipation tubules 24 and the second group of heat dissipation tubules 44, the liquid flows in a one-way circulation of liquid→steam→liquid. The flow resistance is small for the airflow to pass the heat dissipation tubules (the first group of heat dissipation tubules 24 and the second group of heat dissipation tubules 44) and the heat dissipation fins, thus the heat dissipation requirement of the communication apparatus can be satisfied.

In a variation of FIG. 9, the first fan unit 22 may be set up at the first air outlet 27, and the first group of heat dissipation tubules 24 may be set up at the first air inlet 25, thus the partition board 105 in FIG. 9 is not required.

It is appreciated that in another variation of FIG. 9, the first fan unit 22 may be set up at the first air inlet 25, and the first group of heat dissipation tubules 24 may be set up at the first air outlet 27.

Similarly, in another variation of FIG. 9, the second fan unit 42 may be set up at the second air outlet 47, and the second group of heat dissipation tubules 44 may be set up at the second air inlet 45.

The heat exchanger in FIG. 9 may be a top-type heat exchanger.

For the variations of the embodiment, the connection relation between the second group of heat dissipation tubules 44 and the first group of heat dissipation tubules 24 may refer to the description of FIG. 3, and herein is not repeated.

It shall be appreciated that when the heat exchanger 100 as mentioned in the above embodiments is provided for the communication apparatus, the first air passage 20 may be an internal circulation air passage, and the second air passage 40 may be an external circulation air passage.

### Embodiment 2

Referring to FIG. 11, which is a schematic diagram of a heat dissipation method of a heat exchanger according to an embodiment of the present invention.

The heat dissipation method of the heat exchanger includes the following steps.

In step 201, under the action of the first fan unit, the air inside the communication apparatus passes the first air passage, and under the action of the second fan unit, the air outside the communication apparatus passes the second air passage, wherein the first and second air passages are separated from each other.

In step 202, a heat exchange is carried out between the liquid in the first group of heat dissipation tubules and the air inside the communication apparatus passing the first air passage, so that the liquid in the first group of heat dissipation tubules is vaporized into steam by absorbing heat, and the steam flows along the steam manifold to the second group of heat dissipation tubules.

In step 203, a heat exchange is carried out between the air outside the communication apparatus passing the second air passage and the steam passing the second group of heat dissipation tubules, so that the steam passing the second group of heat dissipation tubules is condensed into liquid, which flows into the first group of heat dissipation tubules via a liquid manifold.

The heat dissipation fins are set among the first and second groups of heat dissipation tubules, respectively.

From the above content, it can be seen that in the heat dissipation method of a heat exchanger according to the embodiment of the present invention, the liquid vaporized when being heated flows in a one-way circulation of liquid→steam→liquid. Meanwhile, there is a small flow resistance for the airflow (the air inside and outside the communication apparatus) to pass the heat dissipation tubules and the heat dissipation fins. Therefore, with the power increase of the communication apparatus, the heat dissipation requirement of the communication apparatus can be well satisfied.

### Embodiment 3

A communication apparatus is also provided according to an embodiment of the present invention. The communication apparatus includes a heat exchanger 100 and a cabinet. The cabinet is provided with a single board and the heat exchanger 100 is disposed in the cabinet. Referring to FIG. 3, the heat exchanger 100 includes a first air passage 20 and a second air passage 40. The first air passage 20 and the second air passage 40 are separated from each other. And the first air passage 20 is communicated with the air inside the cabinet (an internal circulation air passage may be formed), and the second air passage 40 is communicated with the air outside the cabinet (an external circulation air passage may be formed). The first air passage 20 is provided with a first fan unit 22 and a first group of heat dissipation tubules 24, and the second air passage 40 is provided with a second fan unit 42 and a second group of heat dissipation tubules 44. The upper ends 247 of the first group of heat dissipation tubules 24 along the gravity direction are communicated via a steam manifold 80 with the upper ends 447 of the second group of heat dissipation tubules 44 along the gravity direction. The lower ends 249 of the first group of heat dissipation tubules 24 along the gravity direction are communicated via a liquid manifold 60 with the lower ends 449 of the second group of heat dissipation tubules 44 along the gravity direction. A closed pipeline, which is filled with liquid vaporized when being heated, is formed by the first group of dissipation tubules 24, the steam manifold 80, the second group of dissipation tubules 44 and the liquid manifold 60. Heat dissipation fins 2411 are set among the first group of dissipation tubules 24 and the second group of dissipation tubules 44, respectively.

From the above content, it can be seen that the first group of heat dissipation tubules 24 and the second group of heat dissipation tubules 44 of the heat exchanger 100 of the communication apparatus according to the embodiment of the present invention are arranged separately. The first group of heat dissipation tubules 24 adopts a first group of heat dissipation tubules 241, and the second group of heat dissipation tubules 44 adopts a second group of heat dissipation tubules 441. The first group of heat dissipation tubules 241 is filled with liquid that is vaporized when being heated and flows in a one-way circulation of liquid→steam→liquid. Meanwhile, there is a small flow resistance for the airflow (the air inside and outside the communication apparatus) to pass the heat dissipation tubules. Therefore, with the increase of the power of the communication apparatus, the heat dissipation requirement of the communication apparatus can be well satisfied.

Further, there is also a small flow resistance for the airflow to pass the heat dissipation fins, and the heat exchange area between the airflow and the outer surfaces of the heat dissipation tubules can be increased by the heat dissipation fins.

The communication apparatus may be an access network outdoor communication apparatus or outdoor base station, etc. The closed pipeline is vacuum and filled with liquid vaporized when being heated.

The upper ends 447 of the second group of heat dissipation tubules 44 along the gravity direction are not lower than the upper ends 247 of the first group of heat dissipation tubules 24, and the lower ends 449 of the second group of heat dissipation tubules 44 are not lower than the lower ends 249 of the first group of heat dissipation tubules 24.

The steam manifold 80 includes a first upper manifold 243 and a second upper manifold 443 communicated with each other via a pipeline 82. The liquid manifold 60 includes a second lower manifold 445 and a first lower manifold 245 communicated with each other via a pipeline 62.

Further, referring to FIGS. 3 and 6, the upper ends 247 of the first group of heat dissipation tubules 24 along the gravity direction are communicated with the first upper manifold 243, and the lower ends 249 of the first group of heat dissipation tubules 24 along the gravity direction are communicated with the first lower manifold 245. Similarly, the lower ends 449 of the second group of heat dissipation tubules 44 along the gravity direction are communicated with the second lower manifold 445, and the upper ends 447 of the second group of heat dissipation tubules 44 along the gravity direction are communicated with the second upper manifold 443.

Referring to FIG. 3, along the gravity direction, the second upper manifold 443 is not lower than the first upper manifold 243, and the second lower manifold 445 is not lower than the first lower manifold 245.

Referring to FIGS. 3-5, the heat exchanger 100 includes a housing 101. A first air inlet 25 and a first air outlet 27 are provided on the first side 102 of the housing 101, and a second air inlet 45 and a second air outlet 47 are provided on the second side 103 of the housing 101. The first side 102 and the second side 103 are opposite to each other, and the first air inlet 25 and the first air outlet 27 are separated from the second air inlet 45 and the second air outlet 47 through a partition board 104. The second fan unit 42 is provided at the second air inlet 45, and the second group of heat dissipation tubules 44 are provided at the second air outlet 47. The first fan unit 22 is provided at the first air inlet 25, and the first group of heat dissipation tubules 24 are provided at the first air outlet 27.

Referring to Embodiment 1, the heat exchanger 100 includes a housing 101. A first air inlet 25, a first air outlet 27 and a second air outlet 47 are provided on a first side 102 of the housing 101, and a second air inlet 45 is provided on a second side 103 of the housing 101. The first side 102 and the second side 103 are opposite to each other, and the first air inlet 25 and the first air outlet 27 are separated from the second air inlet 45 and the second air outlet 47 by a partition board 104. The second fan unit 42 is provided at the second air inlet 45, and the second group of heat dissipation tubules 44 are provided at the second air outlet 47. The first fan unit 22 is provided at the first air inlet 25, and the first group of heat dissipation tubules 24 are provided at the first air outlet 27.

Referring to Embodiment 1, the heat exchanger 100 includes a housing 101. A first air inlet 25, a first air outlet 27 and a second air outlet 47 are provided on a first side 102 of the housing 101, and a second air inlet 45 is provided on a second side 103 of the housing 101. The first side 102 and the second side 103 are opposite to each other, and the first air inlet 25 and the first air outlet 27 are separated from the second air inlet 45 and the second air outlet 47 by a partition board 104. The second fan unit 42 is provided at the second air inlet 45, and the second group of heat dissipation tubules 44 are provided at the second air outlet 47. The first fan unit 22 is provided at the first air outlet 27, and the first group of heat dissipation tubules 24 are provided at the first air inlet 25.

To be noted, please see detailed description of the heat exchanger in Embodiment 1 for the heat exchanger as mentioned in Embodiment 3, and herein is not repeated.

To be noted, “first”, “second”, . . . as mentioned in the above embodiments are serial numbers made for the convenience of describing the above embodiments with reference to the drawings, rather than limitations to the embodiments of the present invention.

The above descriptions just concern the embodiments of the present invention, and the protection scope of the present invention is not limited thereto. Any change or replacement that can be easily conceived by a person skilled in the art within the technical scope disclosed in the present invention shall be covered by the protection scope of the present invention.

What is claimed is:

1. A heat exchanger, comprising a first air passage and a second air passage separated from each other, wherein the first air passage is provided with a first fan unit and a first group of heat dissipation tubules; the second air passage is provided with a second fan unit and a second group of heat dissipation tubules; the upper ends of the first group of heat dissipation tubules along the gravity direction are communicated via a steam manifold with the upper ends of the second group of heat dissipation tubules along the gravity direction, the lower ends of the first group of heat dissipation tubules along the gravity direction are communicated via a liquid manifold with the lower ends of the second group of heat dissipation tubules along the gravity direction; a closed pipeline, which is filled with liquid vaporized when being heated, is formed by the first group of dissipation tubules, the steam manifold, the second group of dissipation tubules and the liquid manifold; and heat dissipation fins are set among the first group of dissipation tubules and the second group of dissipation tubules.

2. The heat exchanger according to claim 1, wherein the steam manifold comprises a first upper manifold and a second upper manifold communicated with each other via a pipeline; and
the liquid manifold comprises a first lower manifold and a second lower manifold communicated with each other via another pipeline.

3. The heat exchanger according to claim 2, wherein the upper ends of the first group of heat dissipation tubules along the gravity direction are communicated with the first upper manifold, and the lower ends of the first group of heat dissipation tubules along the gravity direction are communicated with the first lower manifold; and the upper ends of the second group of heat dissipation tubules along the gravity direction are communicated with the second upper manifold, and the lower ends of the second group of heat dissipation tubules along the gravity direction are communicated with the second lower manifold.

4. The heat exchanger according to claim 3, wherein along the gravity direction, the second upper manifold is not lower than the first upper manifold, and the second lower manifold is not lower than the first lower manifold.

5. The heat exchanger according to claim 1, wherein the heat dissipation fins among the first group of heat dissipation tubules and the second group of heat dissipation tubules are corrugated or zigzag heat dissipation fins.

6. The heat exchanger according to claim 1, wherein the first group of heat dissipation tubules and/or the second group of heat dissipation tubules are tabular heat dissipation tubules.

7. The heat exchanger according to claim 1, wherein the liquid vaporized when being heated is ammonia, acetone or R134A refrigerant.

8. The heat exchanger according to claim 1, wherein the first fan unit is an axial flow fan or a centrifugal fan, and the second fan unit is an axial flow fan or a centrifugal fan.

9. The heat exchanger according to claim 1, wherein the first air passage comprises a first air inlet and a first air outlet, the first fan unit is provided at the first air inlet or the first air outlet, and conversely, the first group of heat dissipation tubules are provided at the first air outlet or the first air inlet.

10. The heat exchanger according to claim 9, wherein the second air passage comprises a second air inlet and a second air outlet, the second fan unit is provided at the second air inlet or the second air outlet, and conversely, the second group of heat dissipation tubules are provided at the second air outlet or the second air inlet.

11. The heat exchanger according to claim 1, wherein the upper ends of the second group of heat dissipation tubules along the gravity direction are not lower than the upper ends of the first group of heat dissipation tubules along the gravity direction, and the lower ends of the second group of heat dissipation tubules along the gravity direction are not lower than the lower ends of the first group of heat dissipation tubules along the gravity direction.

12. A heat dissipation method of heat exchanger, comprising:
the air inside a communication apparatus passing a first air passage under the action of a first fan unit, and the air outside the communication apparatus passing a second air passage under the action of a second fan unit, wherein the first and second air passages are separated from each other;
carrying out a heat exchange between the air inside the communication apparatus passing the first air passage and the liquid in a first group of heat dissipation tubules, so that the liquid in the first group of heat dissipation tubules is vaporized into steam by absorbing heat, and the steam flows along a steam manifold into a second group of heat dissipation tubules; and
carrying out a heat exchange between the air outside the communication apparatus passing the second air passage and the steam passing the second group of heat dissipation tubules, so that the steam passing the second group of heat dissipation tubules is condensed into liquid which flows into the first group of heat dissipation tubules via a liquid manifold.

13. A communication apparatus, comprising a cabinet provided with a single board and a heat exchanger disposed in the cabinet, the heat exchanger comprises a first air passage and a second air passage separated from each other, the first air passage is communicated with the air inside the cabinet, and the second air passage is communicated with the air outside the cabinet, wherein the first air passage is provided with a first fan unit and a first group of heat dissipation tubules; the second air passage is provided with a second fan unit and a second group of heat dissipation tubules; the upper ends of the first group of heat dissipation tubules along the gravity direction are communicated via a steam manifold with the upper ends of the second group of heat dissipation tubules along the gravity direction, the lower ends of the first group of heat dissipation tubules along the gravity direction are communicated via a liquid manifold with the lower ends of the second group of heat dissipation tubules along the gravity direction; a closed pipeline, which is filled with liquid vaporized when being heated, is formed by the first group of dissipation tubules, the steam manifold, the second group of dissipation tubules and the liquid manifold; and heat dissipation fins are set among the first group of dissipation tubules and the second group of dissipation tubules.

14. The communication apparatus according to claim 13, wherein the steam manifold comprises a first upper manifold and a second upper manifold communicated with each other via a pipeline; and
the liquid manifold comprises a first lower manifold and a second lower manifold communicated with each other via another pipeline.

15. The communication apparatus according to claim 14, wherein the upper ends of the first group of heat dissipation tubules along the gravity direction are communicated with the first upper manifold, and the lower ends of the first group of heat dissipation tubules along the gravity direction are communicated with the first lower manifold; and the upper ends of the second group of heat dissipation tubules along the gravity direction are communicated with the second upper manifold, and the lower ends of the second group of heat dissipation tubules along the gravity direction are communicated with the second lower manifold.

16. The communication apparatus according to claim 15, wherein along the gravity direction, the second upper manifold is not lower than the first upper manifold, and the second lower manifold is not lower than the first lower manifold.

17. The communication apparatus according to claim 13, wherein the heat dissipation fins among the first group of heat dissipation tubules and the second group of heat dissipation tubules are corrugated or zigzag heat dissipation fins.

18. The communication apparatus according to claim 13, wherein the upper ends of the second group of heat dissipation tubules along the gravity direction are not lower than the upper ends of the first group of heat dissipation tubules along the gravity direction, and the lower ends of the second group of heat dissipation tubules along the gravity direction are not lower than the lower ends of the first group of heat dissipation tubules along the gravity direction.
